(19) United States
(12) Patent Application Publication
(10) Pub. No.: US 2025/0239510 A1
(43) Pub. Date: Jul. 24, 2025

(54) HIGH CAPACITY HIGH BANDWIDTH NON-VOLATILE MEMORY DEVICE

(71) Applicant: Sandisk Technologies, Inc., Milpitas, CA (US)

(72) Inventors: Nagesh Vodrahalli, Los Altos, CA (US); Rama Kant Shukla, Saratoga, CA (US); Chih Yang Li, Menlo Park, CA (US); Shrikar Bhagath, San Jose, CA (US)

(21) Appl. No.: 18/420,719

(22) Filed: Jan. 23, 2024

(51) Int. Cl. H01L 23/498; H01L 21/48; H01L 25/065; H10B 41/20; H10B 41/35; H10B 43/20; H10B 43/35

(52) U.S. Cl. CPC H01L 23/49827; H01L 21/486; H01L 25/0657; H10B 41/20; H10B 41/35; H10B 43/20; H10B 43/35; H01L 2225/06541

(57) ABSTRACT

A high capacity, high bandwidth non-volatile memory device includes a number of vertically stacked semiconductor dies. Each semiconductor die includes one or more non-volatile storage structures. Through silicon vias (TSVs) are arranged in a pattern on each semiconductor die and are used to route signals lines that directly and independently connect one or more non-volatile storage structures on one or more semiconductor dies to a controller die of the high capacity, high bandwidth non-volatile memory device. Because signal lines and TSVs are used to directly connect each non-volatile storage structure directly to the controller die, the bandwidth capabilities of the high capacity, high bandwidth non-volatile memory device is increased when compared with current non-volatile memory devices.

### BACKGROUND

A three-dimensional (3D) NAND memory device is typically used in various data storage device applications including memory cards, USB drives and solid state drives (SSDs). 3D NAND memory devices are preferred for these data storage applications due to its non-volatile nature, large storage capacity and low cost. However, when compared with other memory device technologies, such as Static Random-Access Memory (SRAM) devices or Dynamic Random-Access Memory (DRAM) devices, 3D NAND memory devices have lower bandwidth and higher access times. As a result, and despite the significantly higher cost and lower storage capabilities when compared with 3D NAND memory devices, SRAM and DRAM memory devices are typically used for high-speed applications.

Accordingly, it would be advantageous to increase the bandwidth capabilities of a 3D NAND memory device without sacrificing the storage capacity of the 3D NAND memory device. This would enable the 3D NAND memory device to be used in high-speed applications.

### SUMMARY

The present application describes a high capacity, high bandwidth non-volatile memory device. The high capacity, high bandwidth non-volatile memory device includes a number of vertically stacked semiconductor dies. In an example, the vertically stacked semiconductor dies are 3D NAND memory dies.

Each semiconductor die of the high capacity, high bandwidth non-volatile memory device has one or more non-volatile storage structures. In an example, the non-volatile storage structures are 3D NAND planes and each non-volatile storage structure includes a number of memory cells. Additionally, each non-volatile storage structure is independently and directly accessible. As such, two or more of the non-volatile storage structures may be directly accessed simultaneously or in parallel.

To increase the bandwidth capabilities of the high capacity, high bandwidth non-volatile memory device, through silicon vias (TSVs) are used to route signal lines between a controller of the high bandwidth, high-capacity non-volatile memory device and each non-volatile storage structure on each semiconductor die. In an example, the TSVs and signal lines are used in lieu of bond wires to interconnect each non-volatile storage structure and/or semiconductor die to a controller die associated with the high capacity, high bandwidth non-volatile memory device. For example, the TSVs provide communication/signal paths between one or more of the non-volatile storage structures on one or more of the vertically stacked semiconductor dies and the controller die. Additionally, one or more horizontal metal layers are used to connect one or more of the non-volatile storage structures on each semiconductor die to each other.

In an example, the TSVs are arranged in a grid pattern (or another pattern) such that at least one TSV is adjacent to each non-volatile storage structure. As such, routing signals between the non-volatile storage structure and a controller die of the high capacity, high bandwidth non-volatile memory device occurs along as short of a communication path as possible.

Each semiconductor die of the high capacity, high bandwidth non-volatile memory device also includes a TSV channel. In an example, the TSV channel is provided in a middle or center portion of each semiconductor die. The TSV channel includes a plurality of TSVs. Each of the plurality of TSVs communicatively couple one or more of the non-volatile storage structures of each semiconductor die to each other and/or to the controller die.

Accordingly, examples of the present disclosure describe a semiconductor device that includes a semiconductor die having a first non-volatile storage structure and a second non-volatile storage structure. A first set of signal lines communicatively couple the first non-volatile storage structure to a controller die of the semiconductor device. In an example, the first set of signal lines are provided in a first set of through silicon vias (TSVs) and enable a first set of data to be directly written to the first non-volatile storage structure. A second set of signal lines communicatively couple the second non-volatile storage structure to the controller die of the semiconductor device. In an example, the second set of signal lines are provided in a second set of TSVs and enable a second set of data to be directly written to the second non-volatile storage structure independently from and in parallel with, the first set of data.

Other examples describe a non-volatile memory device that includes a first semiconductor die having a first non-volatile storage means and a second non-volatile storage means. In an example, the first semiconductor die is stacked on a control means of the non-volatile memory device. The non-volatile memory device also includes a first group of via means adjacent to the first non-volatile storage means and the second non-volatile storage means. In an example, the first group of via means is associated with signal means that directly couple the first non-volatile storage means to the control means of the non-volatile storage memory device and independently directly couple the second non-volatile storage means to the control means of the non-volatile memory device. The non-volatile memory device also includes a second semiconductor die stacked on the first semiconductor die. In an example, the second semiconductor die includes a third non-volatile storage means and a fourth non-volatile storage means. A second group of via means is adjacent to the third non-volatile storage means and the fourth non-volatile storage means. In an example, the second group of via means is associated with signal means that directly couple the third non-volatile storage means to the control means of the non-volatile memory device and independently directly couple the fourth non-volatile storage means to the control means of the non-volatile memory device.

Still other examples describe a method of fabricating a non-volatile memory device having a plurality of through silicon vias (TSVs). In an example, the method includes fabricating a plurality of semiconductor dies. Each semiconductor die of the plurality of semiconductor dies includes a plurality of TSVs and a plurality of memory components. A controller die is placed on a substrate. In an example, the controller die includes a plurality of TSVs. A first semiconductor die of the plurality of semiconductor dies is coupled to a top surface of the controller die such that the plurality of TSVs of the first semiconductor die are aligned with respective TSVs of the controller die. Each memory component is directly coupled to the controller die using signal lines associated with the plurality of TSVs. The controller die and the first semiconductor die are encapsulated with a molding compound.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1 illustrates a high capacity, high bandwidth non-volatile memory device according to an example.

FIG. 2 illustrates a high capacity, high bandwidth non-volatile memory device according to another example.

FIG. 3 illustrates a method for fabricating a semiconductor wafer according to an example.

FIG. 4 illustrates a method for fabricating a semiconductor wafer according to another example.

FIG. 5A-FIG. 5F illustrate different operations of a semiconductor die fabrication process according to an example.

FIG. 6A-FIG. 6C illustrates a semiconductor die stacking process according to an example.

FIG. 7 illustrates a 3D NAND die according to current solutions.

FIG. 8 illustrates a high capacity, high bandwidth non-volatile memory device according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. Examples may be practiced as methods, systems or devices. Accordingly, examples may take the form of a hardware implementation, an entirely software implementation, or an implementation combining software and hardware aspects. The following detailed description is therefore not to be taken in a limiting sense, and the scope of the present disclosure is defined by the appended claims and their equivalents.

As previously described, a 3D NAND memory device is typically used in various data storage device applications. Examples include memory cards, USB drives and solid state drives (SSDs). 3D NAND memory devices are preferred for these data storage applications due to its non-volatile nature, large storage capacity and low cost. However, due to bandwidth limitations, 3D NAND memory devices are often replaced by other memory device technologies for high-speed applications. This is due in part, to the slower access times of 3D NAND memory when compared with the access times of other memory device technologies such as Static Random-Access Memory (SRAM) devices and/or Dynamic Random-Access Memory (DRAM) devices.

For example, SRAM and DRAM devices are often used in graphics processing units (GPUs) and artificial intelligence (AI) applications due to their superior bandwidth capabilities when compared with 3D NAND memory devices. However, SRAM devices and DRAM devices are volatile memory devices, have higher production costs and lower storage capabilities when compared with 3D NAND memory devices.

To address the above, the present application describes a high capacity, high bandwidth non-volatile memory device. In an example, the high capacity, high bandwidth non-volatile memory device has over one-hundred times the capacity of current SRAM and DRAM devices and has over one-hundred times the bandwidth capabilities of current 3D NAND memory devices.

The high capacity, high bandwidth non-volatile memory device includes a number of vertically stacked semiconductor dies. In an example, the vertically stacked semiconductor dies are 3D NAND memory dies. For example, each semiconductor die has one or more non-volatile storage structures. In an example, each non-volatile storage structure is a 3D NAND plane having a number of different memory cells.

Interconnections between each semiconductor die and/or between various non-volatile storage structures are made using through silicon vias (TSVs) and associated signal lines instead of bond wires. Using TSVs in lieu of bond wires allows each semiconductor die and/or each non-volatile storage structure on each semiconductor die to have separate and independent signal/communication paths with a controller die of the high capacity, high bandwidth non-volatile memory device and/or a process or a host device.

For example, a first TSV (or a first set of TSVs) provides a direct communication/signal path between a first non-volatile storage structure on a semiconductor die and the controller die associated with the high capacity, high bandwidth non-volatile memory device. A second TSV (or a second set of TSVs) provides a direct and independent communication/signal path between a second non-volatile storage structure and the controller die associated with the high capacity, high bandwidth non-volatile memory device.

In an example, the second non-volatile storage structure is on the same semiconductor die as the first non-volatile storage structure. In another example, the second non-volatile storage structure is on a different semiconductor die. Thus, the TSVs provide direct and independent communication paths to each non-volatile storage structure on each semiconductor die. As a result, each non-volatile storage structure is directly and independently accessible from other storage structures. In another example, the TSVs allow each non-volatile storage structure and/or each semiconductor die to be accessed independently and in parallel.

In another example, the TSVs provide a communication/signal path between a first non-volatile storage structure on a first semiconductor die, a first non-volatile storage structure on a second semiconductor die and the controller die. In yet other examples, one or more metal layers provide a communication/signal path between one or more non-volatile storage structures on the same semiconductor die.

In an example, the TSVs are arranged in a grid pattern such that at least one TSV is adjacent to each non-volatile storage structure. As such, routing signals between the non-volatile storage structure and the controller die of the high capacity, high bandwidth non-volatile memory device occurs along as short of a communication/signal path as possible. Although a grid pattern is specifically mentioned, other patterns may be used.

In an example, the location and/or pattern of the various TSVs adjacent and/or between the various non-volatile storage structure is dependent on a level of desired granularity for the high capacity, high bandwidth non-volatile memory device. For example, for finer granularity, more TSVs are provided adjacent to and/or between different non-volatile storage structures. As such, one or more TSVs may be used to provide communication/signal paths between each non-volatile storage structure and the controller die of the high capacity, high bandwidth non-volatile memory device. If less granularity is desired, fewer TSVs are provided adjacent to and/or between different non-volatile storage structures.

In addition to the various TSVs provided between and/or adjacent to the various non-volatile storage structures, each semiconductor die of the high capacity, high bandwidth non-volatile memory device also includes a TSV channel. In an example, the TSV channel is provided in a middle or center portion of each semiconductor die and includes a plurality of TSVs. Each of the plurality of TSVs communicatively couple one or more non-volatile storage structures of each semiconductor die to each other and/or to the controller die.

Accordingly, the high capacity, high bandwidth non-volatile memory device of the present disclosure provides many technical benefits including, but not limited to, increasing the bandwidth capabilities of 3D NAND memory devices while maintaining a higher capacity and a lower production/fabrication costs relative to SRAM devices and/or DRAM devices.

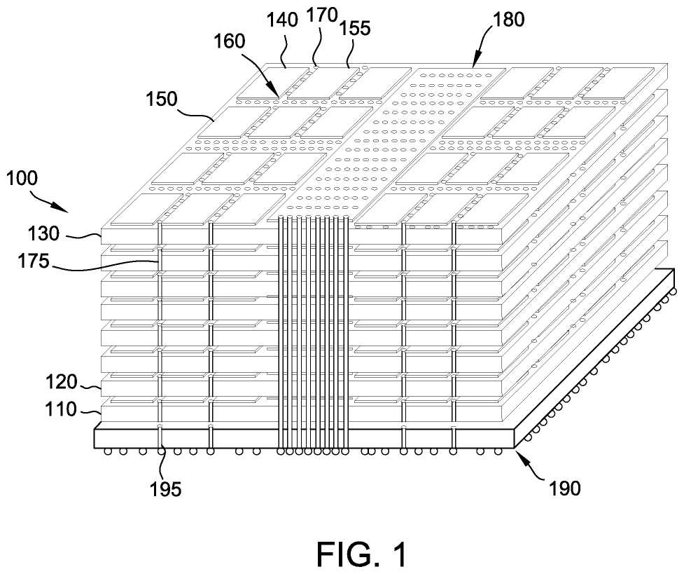

These and other examples will be described in more detail with respect to FIG. 1-FIG. 8.

FIG. 1 illustrates a high capacity, high bandwidth non-volatile memory device 100 according to an example. In an example, the high capacity, high bandwidth non-volatile memory device 100 has one-hundred times (or more) the capacity of current SRAM and DRAM devices and has over one-hundred times (or more) the bandwidth capabilities of current 3D NAND memory devices. Additionally, the high capacity, high bandwidth non-volatile memory device 100 is usable in a number of different high-speed applications including, but not limited to, graphical process units (GPUs) and/or artificial intelligence (AI) implementations, among others.

In an example, the high capacity, high bandwidth non-volatile memory device 100 is a 3D NAND memory device. However, as previously explained, the high capacity, high bandwidth non-volatile memory device 100 has higher bandwidth capabilities when compared with currently available 3D NAND memory devices. For example, the high capacity, high bandwidth non-volatile memory device 100 has bandwidth capabilities of at least 1.5 terabytes (TBs) per second (although higher speeds are contemplated and achievable). Additionally, the high capacity, high bandwidth non-volatile memory device 100 has a higher capacity when compared with currently available 3D NAND memory devices as well as higher capacity when compared with DRAM and SRAM memory devices. For example, the high capacity, high bandwidth non-volatile memory device 100 has at least two TB of capacity (although a higher capacity is contemplated and achievable).

In an example, the high capacity, high bandwidth non-volatile memory device 100 includes a number of semiconductor dies. In an example, the dimensions of each semiconductor die is eight millimeters (mm) by ten mm. Although specific dimensions are given, the semiconductor dies may have any suitable dimensions and may be based, at least in part, on a number of non-volatile storage structures included on the semiconductor die.

In an example, the high capacity, high bandwidth non-volatile memory device 100 includes a first semiconductor die 110, a second semiconductor die 120 and a Nth semiconductor die 130. In the example shown, the high capacity, high bandwidth non-volatile memory device 100 has eight semiconductor dies. Although eight semiconductor dies are shown, the high capacity, high bandwidth non-volatile memory device 100 may include any number of semiconductor dies. For example, the high capacity, high bandwidth non-volatile memory device 100 can include sixteen semiconductor dies or thirty-two (or more) semiconductor dies.

In an example, each semiconductor die includes one or more non-volatile storage structures. For example, the Nth semiconductor die 130 includes a first non-volatile storage structure 140 and a second non-volatile storage structure 150. Although a first non-volatile storage structure 140 and a second non-volatile storage structure 150 are specifically mentioned, each semiconductor die includes any number of non-volatile storage structures. For example, each semiconductor die includes at least twenty-four non-volatile storage structures. Although twenty-four non-volatile storage structures are mentioned, the high capacity, high bandwidth non-volatile memory device 100 can have more (or fewer) than twenty-four non-volatile storage structures.

In an example, each non-volatile storage structure is accessed independently, but in parallel, with other non-volatile storage structures. For example, the first non-volatile storage structure 140 is accessed independently from, but in parallel with, the second non-volatile storage structure 150.

To accomplish this, each non-volatile storage structure is associated with its own set of signal lines that directly couple the non-volatile storage structure to a controller die 190 of the high capacity, high bandwidth non-volatile memory device 100. For example, the first non-volatile storage structure 140 is associated with a first set of signal lines (and associated TSVs) and the second non-volatile storage structure 150 is associated with a second set of signal lines (and associated TSVs). In an example, each set of signal lines includes or supports eight signals/lines. In other examples, each set of signal lines can support anywhere from eight signal up to two hundred fifty-six (or more) signals.

In an example, each of the first non-volatile storage structure 140 and the second non-volatile storage structure 150 are 3D NAND devices. In an example, each 3D NAND device includes one or more planes and each plane includes one or more memory cells.

As shown in FIG. 1, each semiconductor die of the high capacity, high bandwidth non-volatile memory device 100 is vertically stacked on top of each other. For example, the second semiconductor die 120 is stacked on top of the first semiconductor die 110 and the Nth semiconductor die 130 is stacked on top of the N−1 semiconductor die. In an example, thirty-two (or more semiconductor dies may be stacked on top of one another. Regardless of the number of semiconductor dies, interconnections between the various semiconductor dies are made by various through silicon vias (TSVs). Each TSV enables each non-volatile memory structure to be directly and independently accessed (e.g., receive data/instructions from the controller die 190 of the high capacity, high bandwidth non-volatile memory device 100 and/or provide data to the controller die 190 of the high capacity, high bandwidth non-volatile memory device 100. This configuration is unlike current 3D NAND memory devices.

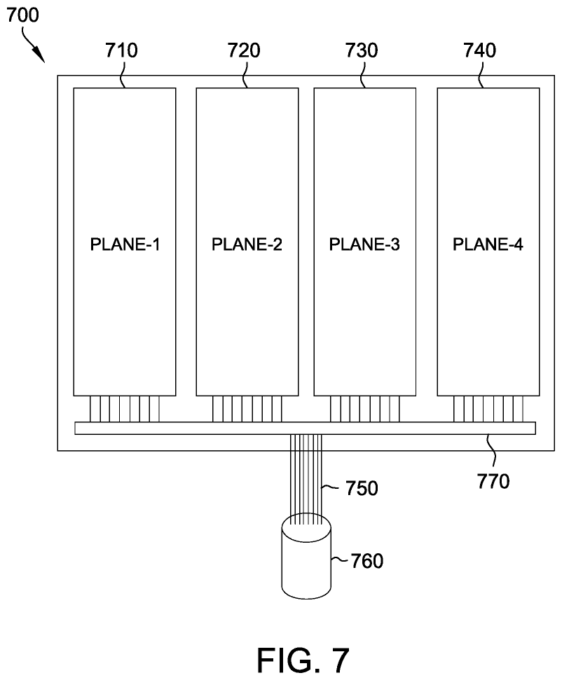

For example and referring to FIG. 7, FIG. 7 illustrates a 3D NAND die 700 according to current solutions. As shown in FIG. 7, the 3D NAND die 700 includes four planes: Plane-1 710, Plane-2 720, Plane-3 730 and Plane-4 740. An eight-bit input/output (I/O) line 750, having eight signal lines, enables the 3D NAND die 700 to receive data 760 (e.g., from a controller die or another component associated with the 3D NAND die 700).

When the eight-bit I/O line 750 is coupled to the 3D NAND die 700, a component 770 (e.g., a multiplexer) associated with the 3D NAND die 700 distributes the signals using other signal lines, which enables Plane-1 710, Plane-2 720, Plane-3 730 and Plane-4 740 to be accessed in parallel.

For example, a single eight-bit I/O line 750 is communicatively coupled to the component 770. Four different sets of additional signal lines communicatively couple each plane to the component 770. However, regardless of the number of planes in the 3D NAND die 700, and regardless of whether the planes are accessed in parallel, the single eight-bit I/O line 750 is the only path by which data 760 is provided to each of the planes. As such, the bandwidth capabilities of the 3D NAND die 700 is limited.

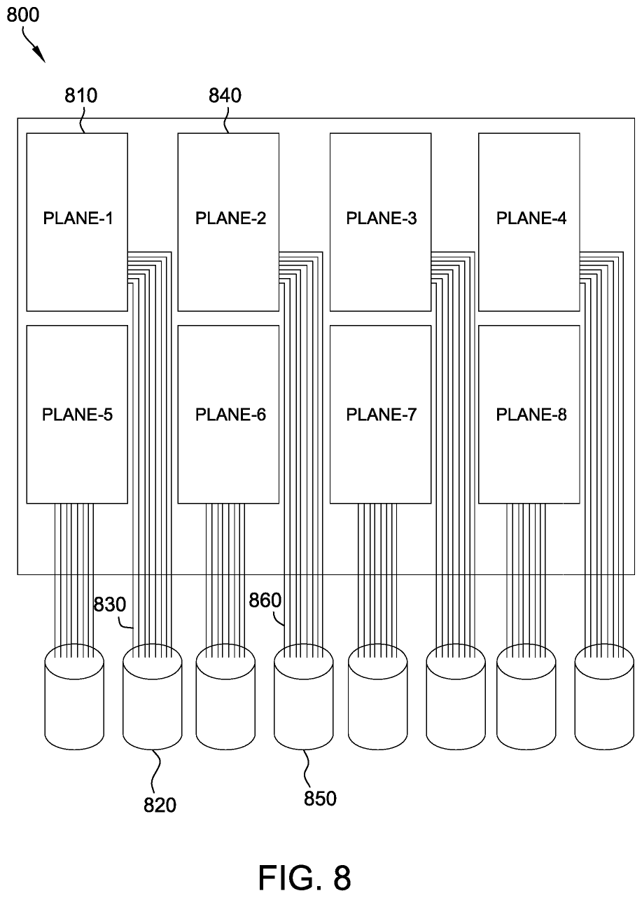

FIG. 8 illustrates a semiconductor die 800 for a high capacity, high bandwidth non-volatile memory device according to an example. In an example, the semiconductor die 800 is similar to one or more of the first semiconductor die 110, the second semiconductor die 120 and the Nth semiconductor die 130 shown and described with respect to FIG. 1.

In an example, the semiconductor die 800 includes one or more non-volatile storage structures. For example, FIG. 8 illustrates that the semiconductor die 800 includes eight non-volatile storage structures. Although eight non-volatile storage structures are shown and described, the semiconductor die 800 can include any number of non-volatile storage structures.

In an example, each of the non-volatile storage structures are 3D NAND devices (e.g., NAND array planes). For example, the semiconductor die 800 includes Plane-1 810, Plane-2 840, Plane-3, Plane-4, Plane-5, Plane-6, Plane-7 and Plane-8. Additionally, each non-volatile storage structure includes, or is associated with, its own set signal lines. For example, Plane-1 810 is associated with a first set of signal lines 830, Plane-2 840 is associated with a second set of signal lines 860 and so on.

In an example, each set of signal lines are eight-bit I/O lines having eight separate signal lines. Although eight signal lines are shown and described, each set of signal lines may have any number of signal lines. For example, each set of signal lines can support up to two hundred fifty-six (or more) lines/signals. In an example, each signal line from each set of signal lines is provided within, or otherwise associated with a through silicon via (TSV). Each set of signal lines enables data associated with each set of signal lines to be input directly into each non-volatile storage structure 810.

For example, the first set of signal lines 830 associated with Plane-1 810 enables a first data 820 (or a first portion of data) to be directly written to and/or read from Plane-1 810. Likewise, the second set of signal lines 860 associated with Plane-2 840 enables second data 850 (or a second portion of data) that is different from the first data 820 to be directly written to and/or read from Plane-2 840.

Because each non-volatile storage structure is associated with its own set of signal lines, data is directly written to, and/or directly read from, each non-volatile storage structure independently and in parallel. This is in contrast to the 3D NAND die 700 shown and described with respect to FIG. 7 that requires a multiplexer or other component to divide a single eight-bit I/O line associated with the 3D NAND die 700 into different signal lines/paths within the 3D NAND die 700. As a result, much higher bandwidth is achieved by the semiconductor die 800 of FIG. 8 when compared with the 3D NAND die 700 of FIG. 7.

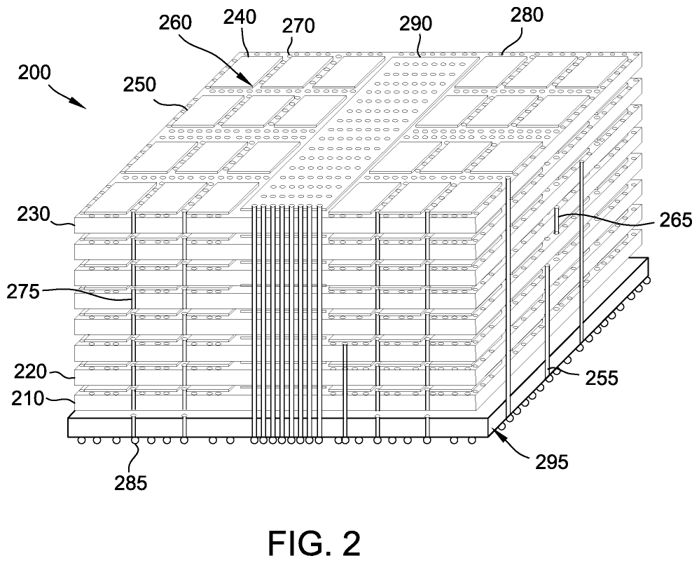

Referring back to FIG. 2, in an example and as previously described, each signal line in each set of signal lines is associated with a TSV. In an example, the TSVs are arranged in a grid pattern that includes a number of rows and/or columns. The rows and/or columns of TSVs are also referred to as groups of TSVs. Although a grid pattern is specifically mentioned, other patterns may be used.

In an example, each semiconductor die has the same pattern or a similar pattern. For example, the arrangement of the TSVs on the Nth semiconductor die 130 is the same or is similar to the arrangement of the TSVs on the first semiconductor die 110. As such, when the semiconductor dies are stacked, the TSVs of each semiconductor die are aligned. Additionally, the TSVs extend throughout the entire high capacity, high bandwidth non-volatile memory device 100.

In an example, the TSVs are arranged such that one or more TSVs are adjacent to one or more non-volatile storage structures of each semiconductor die. In another example, one or more TSVs are provided between adjacent non-volatile storage structures. In such an arrangement, each semiconductor die and/or each non-volatile storage structure of each semiconductor die may be directly and independently accessed and/or programmed. For example, a first TSV (or a first group of TSVs) provide a first communication/signal path between a first non-volatile storage structure on a first semiconductor die and a controller die 190 of the high capacity, high bandwidth non-volatile memory device 100. Likewise, a second TSV (or a second group of TSVs) provide a second communication/signal path between a second non-volatile storage structure on the first semiconductor die and the controller die 190 of the high capacity, high bandwidth non-volatile memory device 100.

In another example, the second TSV (or the second group of TSVs) provide a second communication/signal path between a second non-volatile storage structure on a second semiconductor die and the controller die 190 of the high capacity, high bandwidth non-volatile memory device 100. As such, each non-volatile storage structure on the same semiconductor die (or on different semiconductor dies) are accessible independently of each other. Although the non-volatile storage structures are accessible independently of each other, the TSVs allow one or more of the non-volatile storage structures to be accessed in parallel.

For example, the TSVs enable a first non-volatile storage structure on a first semiconductor die to be directly accessed independently from, and in parallel with, a second non-volatile storage structure on the first semiconductor die. In another example, the TSVs enable a first non-volatile storage structure on a first semiconductor die to be directly accessed in independently and in parallel with a second non-volatile storage structure on a second semiconductor die. In yet another example, a single TSV (or a groups of TSVs) interconnect one or more non-volatile storage structures on a first semiconductor die to one or more non-volatile storage structures on a second semiconductor die.

In an example, two or more non-volatile storage structures are grouped together (e.g., logically grouped) to form independent memory areas. The two or more non-volatile storage structures may be on the same semiconductor die or different semiconductor dies. When non-volatile storage structures are grouped, one or more TSVs and associated signal lines provide communication/signal paths to each non-volatile storage structure in the group. For example, a first TSV provides a first communication/signal path to a first non-volatile storage structure in the group and a second TSV provides a second communication/signal path to a second non-volatile storage structure in the group.

Additionally, the TSVs are positioned adjacent, near and/or between one or more non-volatile storage structures to provide as short a signal path as possible between the various non-volatile storage structures, the various semiconductor dies and/or a controller die 190 of the high capacity, high bandwidth non-volatile memory device 100. In an example, the shorter the communication path between the various non-volatile storage structures, the various semiconductor dies and/or the controller die 190, the higher the bandwidth capabilities of the high capacity, high bandwidth non-volatile memory device 100.

In an example, the Nth semiconductor die 130 includes a first row of TSVs 160. The first row of TSVs 160 is provided between the first non-volatile storage structure 140 and the second non-volatile storage structure 150. Additionally, the Nth semiconductor die 130 includes a first column of TSVs 170. The first column of TSVs 170 is provided between the first non-volatile storage structure 140 and a third non-volatile storage structure 155.

The first row of TSVs 160 extend at least partially across a width of the Nth semiconductor die 130. Additionally, the first column of TSVs 170 extend at least partially across a length of the Nth semiconductor die 130. Although a specific arrangement and pattern of TSVs are shown, the TSVs may be arranged in any pattern and each row or column of TSVs may include any number of TSVs.

Each semiconductor die also includes a TSV channel that includes a number of different TSVs. For example, the Nth semiconductor die 130 includes a TSV channel 180. In an example, the TSV channel 180 is provided in middle portion of the Nth semiconductor die 130. In an example, the TSV channel 180 includes one thousand twenty-four TSVs. Although a specific number of TSVs have been given, this is for example purposes only and the TSV channel 180 can include any number of TSVs.

As with the other TSVs described herein, the TSVs in the TSV channel 180 are used to directly couple one or more non-volatile storage structures on the same semiconductor die to the controller die 190. The TSVs in the TSV channel 180 also communicatively couple one or more non-volatile storage structures on two or more semiconductor dies to the controller die 190.

For example, a first TSV (or a number of TSVs) in the column of TSVs 170 (and/or one or more TSVs in the row of TSVs 160) communicatively couples the first non-volatile storage structure 140 on the Nth semiconductor die 130 and/or the second non-volatile storage structure 150 on the Nth semiconductor die to the controller die 190. In another example, a first TSV (or a number of TSVs) in the column of TSVs 170 (and/or one or more TSVs in the row of TSVs 160) communicatively couples the first non-volatile storage structure 140 on the Nth semiconductor die 130 to a first non-volatile storage structure on a N-1 semiconductor die. In such an example, the first TSV in the column of TSVs 170 also communicatively couples the first non-volatile storage structure 140 on the Nth semiconductor die 130 and the first non-volatile storage structure on the N-1 semiconductor die to the controller die 190.

Although specific examples are given, each TSV of the high capacity, high bandwidth non-volatile memory device 100 is used to interconnect one or more semiconductor dies and/or one or more non-volatile storage structures on one or more of the semiconductor dies to each other and/or to the controller die 190.

The TSVs are also used to route input/output (I/O) signals, power signals and/or ground signals from the various non-volatile storage structures on each semiconductor die to the controller die 190 of the high capacity, high bandwidth non-volatile memory device 100. The controller die 190 is operable to route signals to/from the various semiconductor dies, control garbage collection operations, control error correction operations, control refresh operations and/or manage the traffic of the various signals that are transmitted to the various semiconductor dies though the TSVs.

The controller die 190 also includes one or more connection points 195. In an example, the connection points are micro-bumps, solder balls, or other connection/communication mechanisms that enable the high capacity, high bandwidth non-volatile memory device 100 to be communicatively coupled to another device (e.g., a controller, another high capacity, high bandwidth non-volatile memory device, a substrate, a printed circuit board (PCB)). As such, the connection points 195 are provided on a bottom surface of the controller die 190.

In an example, each connection point 195 is associated with a particular TSV. Accordingly, one or more of the TSVs of the high capacity, high bandwidth non-volatile memory device 100 extend from the connection points 195, through the controller die 190 and through one or more of the semiconductor dies and/or to one or more of the non-volatile storage structures. Thus, there may be a direct communication path between a connection point and a particular non-volatile storage structure.

FIG. 2 illustrates a high capacity, high bandwidth non-volatile memory device 200 according to another example. In an example, the high capacity, high bandwidth non-volatile memory device 200 is similar to the high capacity, high bandwidth non-volatile memory device 100 shown and described with respect to FIG. 1. For example, the high capacity, high bandwidth non-volatile memory device 200 includes a first semiconductor die 210, a second semiconductor die 220 and a Nth semiconductor die 230 vertically stacked on top of each other.

Additionally, each semiconductor die includes one or more non-volatile storage structures. For example, the Nth semiconductor die 230 includes a first non-volatile storage structure 240 and a second non-volatile storage structure 250. Although two non-volatile storage structures are specifically mentioned, each semiconductor die may include any number of non-volatile storage structures.

Each semiconductor die of the high capacity, high bandwidth non-volatile memory device 200 also includes a number of TSVs arranged in a pattern. For example, each semiconductor die of the high capacity, high bandwidth non-volatile memory device 200 includes one or more rows of TSVs 260 and one or more columns of TSVs 270 such as described with respect to FIG. 1. However, in this example, each semiconductor die includes various TSVs provided around a perimeter 280. Although additional TSVs are shown around the perimeter 280 of each semiconductor die, this is for example purposes only and for showing that the TSVs may be arranged in any pattern.

Additionally, and like the high capacity, high bandwidth non-volatile memory device 100 of FIG. 1, the high capacity, high bandwidth non-volatile memory device 200 includes a TSV channel 290. In an example, the TSV channel 290 functions in a similar manner as the TSV channel 180 shown and described with respect to FIG. 1.

In an example, each TSV in the high capacity, high bandwidth non-volatile memory device 200 from a controller extends from a controller die 295 (and/or from one or more connection points 285 associated with the controller die 295) through each semiconductor die. For example, the TSV 275 extends from a connection point 285 of the controller die 295, through the first semiconductor die 210, the second semiconductor die 220 to the Nth semiconductor die 230.

In another example, a TSV may extend partially through the high capacity, high bandwidth non-volatile memory device 200. For example, the TSV 265 only extends through two semiconductor dies while the TSV 255 extends from the controller die 295 and partially through the high capacity, high bandwidth non-volatile memory device 200.

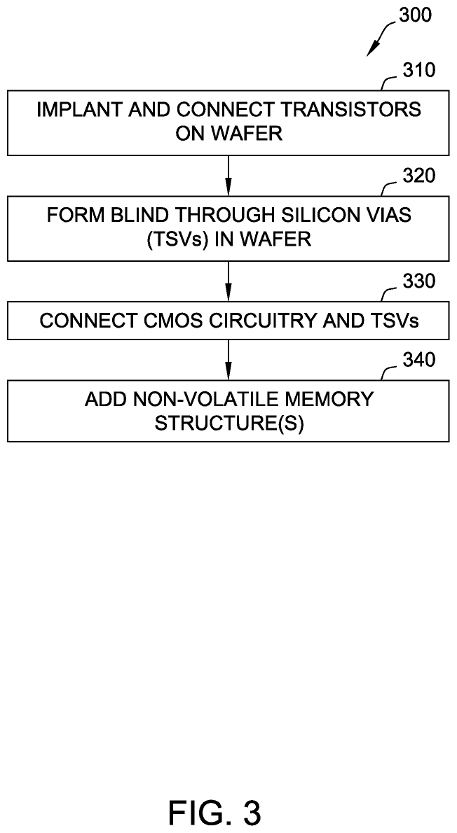

FIG. 3 illustrates a method 300 for fabricating a semiconductor wafer according to an example. In an example, the semiconductor wafer fabrication process is used to fabricate one or more semiconductor dies that are used in the high capacity, high bandwidth non-volatile memory device 100 shown and described with respect to FIG. 1 and/or the high capacity, high bandwidth non-volatile memory device 200 shown and described with respect to FIG. 2. In this example, the semiconductor wafer includes CMOS circuitry and NAND circuitry and each layer is formed or fabricated on the same wafer.

Method 300 begins with an implantation process in which one or more transistors are implanted and connected (310) on a wafer. In an example, the wafer is a CMOS wafer. Additionally, any suitable transistor implantation and/or connection process may be used.

When the transistors have been implanted and connected, one or more through silicon vias (TSVs) are formed (320) in the wafer. In an example, the TSVs are blind TSVs. As such, the TSVs extend at least partially through the CMOS wafer.

In an example, some of the TSVs are arranged in a pattern or grid. For example, the TSVs are arranged such that they will be adjacent to one or more non-volatile memory structures such as previously described. In other examples, other TSVs are arranged to form a TSV channel. In an example, the TSV channel is formed in a middle portion of the CMOS wafer.

When the TSVs have been formed, a metallization process is initiated. In an example, the metallization process is a process in which CMOS circuitry is connected (330) to the TSVs.

One or more non-volatile memory structures are then added (340) to the wafer. In an example, the non-volatile memory structures are 3D NAND memory structures. Additionally, the 3D NAND memory structures are placed on the wafer such that the structures are adjacent to one or more of the groups of TSVs and/or the TSV channel.

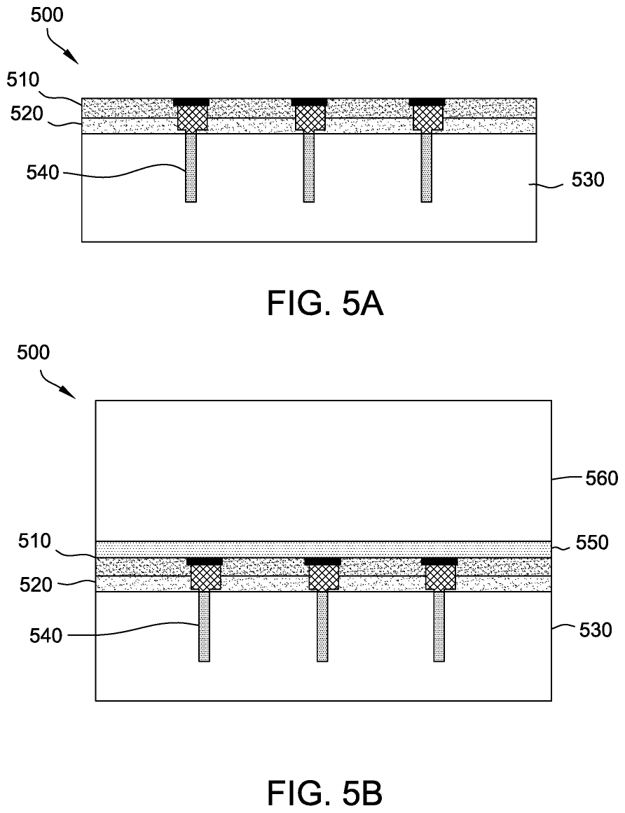

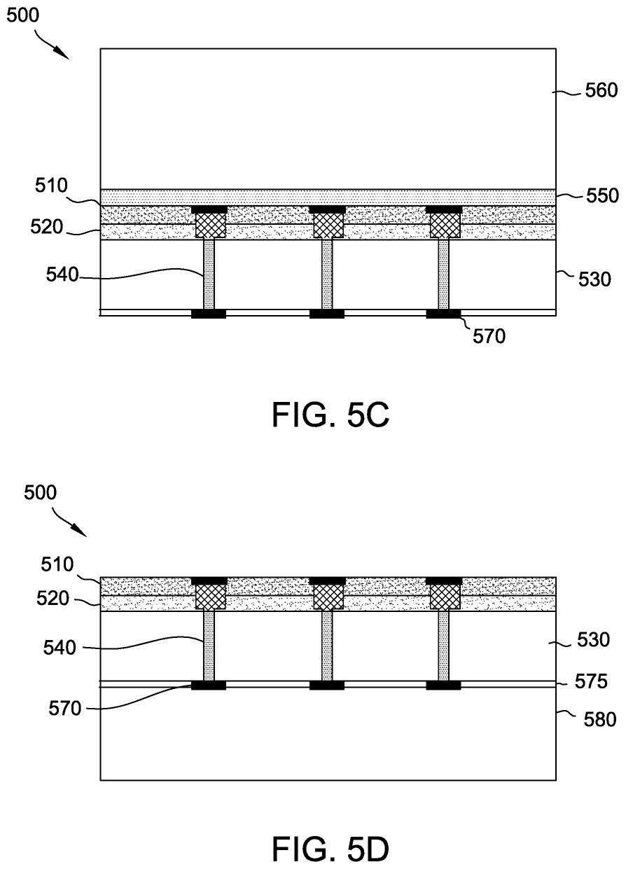

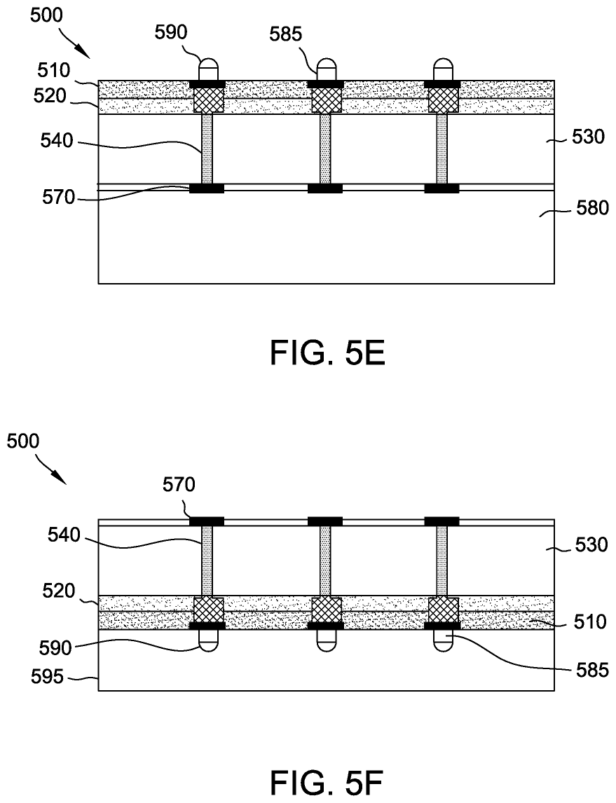

Once the non-volatile memory structures have been added, a top surface of the wafer is complete. As will be described in greater detail with respect to FIG. 5A-FIG. 5F, additional processes/operations are performed to prepare the wafer for bonding.

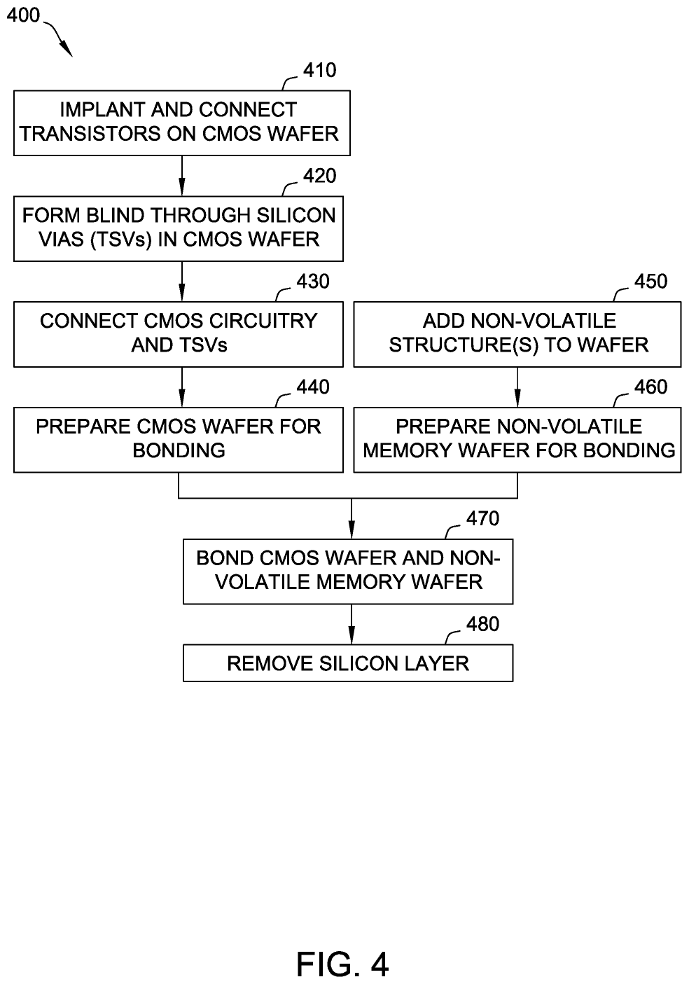

FIG. 4 illustrates a method 400 for fabricating a semiconductor wafer according to another example. In an example, the semiconductor wafer fabrication process is used to fabricate one or more semiconductor dies that are used in the high capacity, high bandwidth non-volatile memory device 100 shown and described with respect to FIG. 1 and/or the high capacity, high bandwidth non-volatile memory device 200 shown and described with respect to FIG. 2. In this example, the semiconductor wafer includes CMOS circuitry and NAND circuitry and each layer is formed on separate wafers. The wafers are then bonded together. As such, one or more of the operations shown and described with respect to FIG. 4 may be performed in sequence or be performed in parallel.

Method 400 begins with an implantation process in which one or more transistors are implanted and connected (410) on a CMOS wafer. In an example, any suitable process can be used to implant the transistors on the CMOS wafer.

When the transistors have been implanted and connected on the CMOS wafer, one or more through silicon vias (TSVs) are formed (420) in the wafer. In an example, the TSVs are blind TSVs. As such, the TSVs extend at least partially through the CMOS wafer.

In an example, the TSVs are arranged in a pattern or grid. For example, the TSVs are arranged such that they will be adjacent to one or more non-volatile memory structures such as previously described. In other examples, the TSVs are arranged to form a TSV channel. In an example, the TSV channel is formed in a middle portion of the CMOS wafer.

Once the TSVs have been formed in the CMOS wafer, a metallization process is initiated. During the metallization process, CMOS circuitry is connected (430) to the TSVs. The CMOS wafer is then prepared (440) for a subsequent bonding process.

The method 400 also includes fabricating a non-volatile memory layer or a non-volatile memory wafer. In an example, the non-volatile memory wafer is a 3D NAND memory wafer. Additionally, the preparation of the non-volatile memory wafer may occur simultaneously with one or more of the operations previously described. In another example, the operations for fabricating the non-volatile memory wafer occurs before or after the fabrication of the CMOS wafer.

In an example, the non-volatile memory wafer is prepared when one or more non-volatile memory structures (e.g., 3D NAND memory structures or layer) are added (450) to a wafer. In an example, any suitable method of adding non-volatile memory structure to a wafer may be used. Once the non-volatile memory structures have been added to the wafer, the non-volatile memory wafer is prepared (460) for bonding. In an example, the non-volatile memory wafer is prepared for bonding by adding one or more micro-bumps, adhesives or other connection mechanisms to a top surface of the non-volatile memory wafer.

When the CMOS wafer and the NAND wafer have been prepared for bonding, the CMOS wafer and the non-volatile memory wafer are bonded (470). In an example, the CMOS wafer and the non-volatile memory wafer are bonded face-to-face (e.g., device layer to device layer). A silicon layer is then removed (480) from one or more of the non-volatile memory wafer and/or the CMOS wafer. A surface of the resulting structure is complete. As will be described in greater detail with respect to FIG. 5A-FIG. 5F, additional processes/operations are performed to prepare the non-volatile memory wafer for bonding.

FIG. 5A-FIG. 5F illustrate different operations of a semiconductor die fabrication process according to an example. The semiconductor die fabrication process may be used to fabricate one or more semiconductor dies (e.g., the first semiconductor die 110 (FIG. 1)) for a high capacity, high bandwidth non-volatile memory device (e.g., the high capacity, high bandwidth non-volatile memory device 100 (FIG. 1)).

FIG. 5A illustrates a semiconductor wafer 500 according to an example. In an example, the semiconductor wafer 500 is the result of the various operations that were executed or otherwise performed as part the method 300 shown and described with respect to FIG. 3 and/or the method 400 shown and described with respect to FIG. 4.

In an example, the semiconductor wafer 500 includes a non-volatile memory layer 510 (e.g., a 3D NAND layer) and a CMOS layer 520. Additionally, the semiconductor wafer includes one or more TSVs 540 that extend through a silicon layer 530. In an example, the TSVs 540 are blind TSVs that extend partially through the silicon layer 530. The TSVs may be part of a TSV channel and/or arranged in a grid or pattern such as previously described.

FIG. 5B illustrates a second operation of the fabrication process in which a first carrier layer 560 is bonded to the non-volatile memory layer 510 of the semiconductor wafer 500. In an example, the first carrier layer 560 is temperature bonded to the non-volatile memory layer 510 using an adhesive 550 or other bonding material.

When the first carrier layer 560 has been bonded to the non-volatile memory layer 510, the silicon layer 530 is thinned or reduced. In an example, the silicon layer 530 is thinned to expose at least a portion of the TSVs 540. The silicon layer 530 is thinned and/or the TSVs 540 are exposed by any suitable process. For example, an etching process (e.g., a plasma etching process) is used to reduce the thickness of the silicon layer 530 and/or to expose the TSVs 540. As shown in FIG. 5C, once the silicon layer 530 has been thinned, micro-pads 570 are formed or are otherwise provided on each TSV 540.

FIG. 5D illustrates another operation of the fabrication process in which a second carrier layer 580 is bonded to the CMOS layer 520 (or the silicon layer 530) of the semiconductor wafer 500 according to an example. Like the first carrier layer 560, the second carrier layer 580 is bonded to the CMOS layer 520 using an adhesive 575 or another bonding material. As shown in FIG. 5D, once the second carrier layer 580 is bonded to the CMOS layer 520, the first carrier layer 560 is removed from the semiconductor wafer 500.

FIG. 5E illustrates another operation of the fabrication process according to an example. As shown in FIG. 5E, once the first carrier layer 560 has been removed, micro-bumps 590 are formed on various micro-pads 585 of the non-volatile memory layer 510.

When the micro-bumps 590 have been formed, the semiconductor wafer 500 is mounted on dicing tape and the second carrier layer 580 is removed. For example, FIG. 5F shows the semiconductor wafer 500 being mounted to dicing tape 595. Additionally, the second carrier layer 580 has been removed which exposes the micro-pads 570 on the CMOS layer 520. The semiconductor wafer 500 may then undergo a singulation process in which individual semiconductor dies are separated from the semiconductor wafer 500.

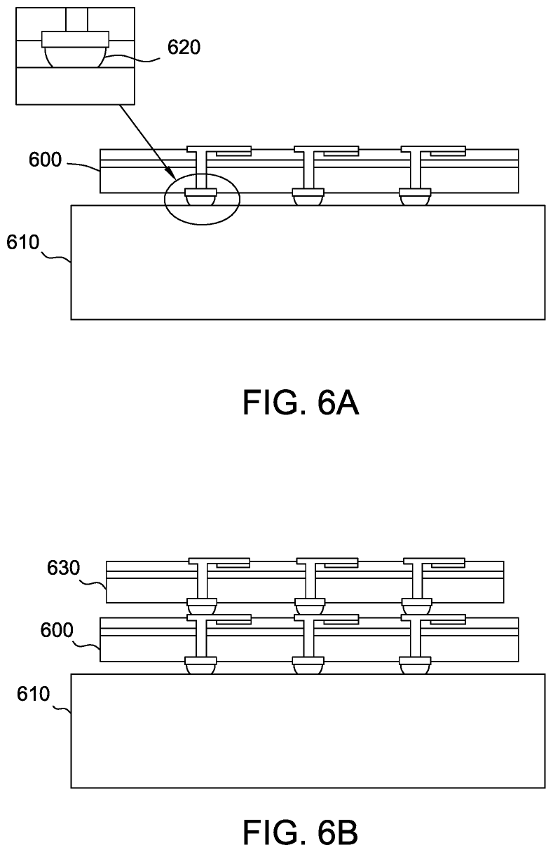

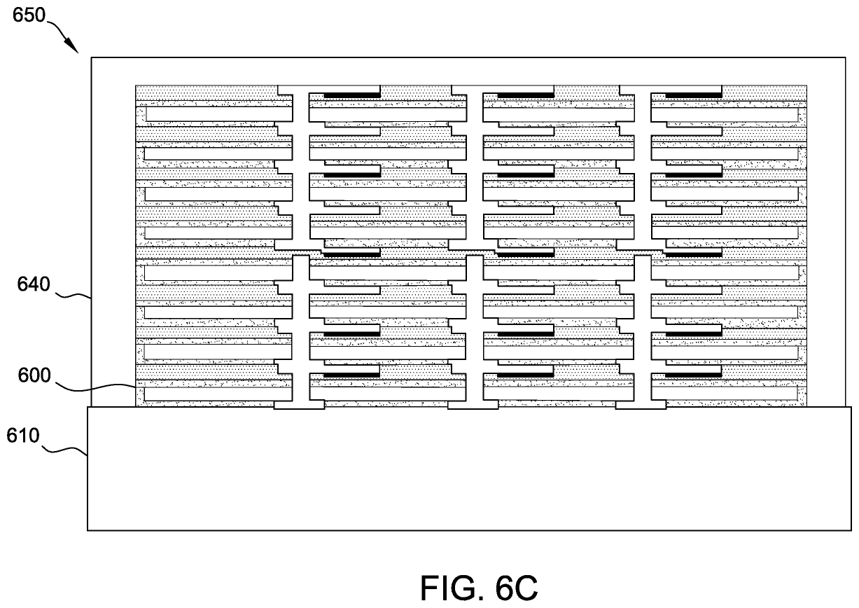

FIG. 6A-FIG. 6C illustrates a semiconductor die stacking process according to an example. In an example, the semiconductor die stacking process shown in FIG. 6A-FIG. 6C uses the semiconductor dies that have been separated from the semiconductor wafer 500 shown in FIG. 5A-FIG. 5F to make the high capacity, high bandwidth non-volatile memory device 100 shown and described with respect to FIG. 1 and/or the high capacity, high bandwidth non-volatile memory device 200 shown and described with respect to FIG. 2.

For example and as shown in FIG. 6A, a first semiconductor die 600 is placed and/or coupled to a substrate 610. In an example, the first semiconductor die 600 is a controller die. In an example, the controller die 600 includes a number of TSVs. The TSVs are arranged in pattern or a grid. The TSVs may also be arranged to form a TSV channel.

The first semiconductor die 600 is bonded to the substrate 610 using a solder ball 620 or other connection mechanism. Once the semiconductor die 600 is placed on the substrate, a reflow process is initiated which melts the solder ball 620. In another example, the semiconductor die 600 is placed on the substrate 610 and a reflow process (e.g. a mass reflow process) is not initiated until all semiconductor dies have been stacked.

Once the first semiconductor die 600 has been placed on and/or bonded to the substrate 610, a second semiconductor die 630 (FIG. 6B) is placed on and/or bonded to a top surface of the first semiconductor die 600. This process continues until the desired amount of semiconductor dies have been stacked on top of each other. In an example, during the stacking process, the TSVs of each semiconductor die are aligned with the other TSVs which creates a communication path between a top-most semiconductor die and the controller die.

Once the desired number of semiconductor dies have been stacked, signal lines are routed through the TSVs enabling each memory component on each semiconductor die to be directly coupled to the substrate. A molding compound 640 is used to encapsulate the structure and the high capacity, high bandwidth non-volatile memory device 650 has been created.

Examples of the present application describe a semiconductor device, comprising: a semiconductor die having a first non-volatile storage structure and a second non-volatile storage structure; a first set of signal lines communicatively coupling the first non-volatile storage structure to a controller die of the semiconductor device, the first set of signal lines provided in a first set of through silicon vias (TSVs) and enabling a first set of data to be directly written to the first non-volatile storage structure; and a second set of signal lines communicatively coupling the second non-volatile storage structure to the controller die of the semiconductor device, the second set of signal lines provided in a second set of TSVs and enabling a second set of data to be directly written to the second non-volatile storage structure independently from, and in parallel with, the first set of data. In an example, the semiconductor also includes a TSV channel, the TSV channel including at least one of a first signal line from the first set of signal lines and a first signal line from the second set of signal lines. In an example, the TSV channel is provided in a middle portion of the semiconductor die. In an example, at least a portion of the first set of TSVs are positioned between the first non-volatile storage structure and the second non-volatile storage structure. In an example, the semiconductor die is a first semiconductor die, the semiconductor device further comprising: a second semiconductor die stacked on the first semiconductor die and having a third non-volatile storage structure and a fourth non-volatile storage structure; a third set of signal lines communicatively coupling the third non-volatile storage structure to the controller die of the semiconductor device, the third set of signal lines provided in a third set of TSVs and enabling a third set of data to be directly written to the third non-volatile storage structure independently from, and in parallel with, the first set of data and the second set of data; and a fourth set of signal lines communicatively coupling the fourth non-volatile storage structure to the controller die of the semiconductor device, the fourth set of signal lines provided in a fourth set of TSVs and enabling a fourth set of data to be directly written to the fourth non-volatile storage structure independently from and in parallel with, the first set of data, the second set of data and the third set of data. In an example, at least one TSV in the first group of TSVs and at least one TSV is the third group of TSVs communicatively couple the first non-volatile storage structure and the third non-volatile storage structure. In an example, at least one TSV from the third set of TSVs and at least one TSV from the fourth set of TSVs are positioned between the third non-volatile storage structure and the fourth non-volatile storage structure. In an example, the first non-volatile storage structure and the second non-volatile storage structure are three dimensional (3D) NAND planes. In an example, the semiconductor device also includes a plurality of connection points provided on a bottom surface of the controller die, wherein each connection point of the plurality of connection points is associated with a TSV in the first group of TSVs and the second group of TSVs.

Examples also describe a non-volatile memory device, comprising: a first semiconductor die having a first non-volatile storage means and a second non-volatile storage means, the first semiconductor die being stacked on a control means of the non-volatile memory device; a first group of via means adjacent to the first non-volatile storage means and the second non-volatile storage means, the first group of via means being associated with signal means that directly couple the first non-volatile storage means to the control means of the non-volatile storage memory device and independently directly couple the second non-volatile storage means to the control means of the non-volatile memory device; a second semiconductor die stacked on the first semiconductor die, the second semiconductor die having a third non-volatile storage means and a fourth non-volatile storage means; and a second group of via means adjacent to the third non-volatile storage means and the fourth non-volatile storage means, the second group of via means being associated with signal means that directly couple the third non-volatile storage means to the control means of the non-volatile memory device and independently directly couple the fourth non-volatile storage means to the control means of the non-volatile memory device. In an example, the non-volatile memory device also includes a plurality of via means provided on the first semiconductor die, the first plurality of via means being associated with signal means that directly couple one or more of the first non-volatile storage means and the second non-volatile storage means to the control means of the non-volatile memory device. In an example, the plurality of via means is provided in a middle portion of the first semiconductor die. In an example, at least one via means in the first group of via means and at least one via means in the third group of via means communicatively couple the first non-volatile storage means and the third non-volatile storage means. In an example, the first non-volatile storage means is a three-dimensional (3D) NAND plane. In an example, the non-volatile memory device also includes a plurality of connection means provided on a bottom surface of the control means, wherein each connection means of the plurality of connection means is associated with a TSV in the first group of via means and the second group of via means.

Examples also describe a method of fabricating a non-volatile memory device having a plurality of through silicon vias (TSVs) comprising: fabricating a plurality of semiconductor dies, each semiconductor die of the plurality of semiconductor dies having a plurality of TSVs and a plurality of memory components; placing a controller die on a substrate, the controller die including a plurality of TSVs; coupling a first semiconductor die of the plurality of semiconductor dies to a top surface of the controller die such that the plurality of TSVs of the first semiconductor die are aligned with respective TSVs of the controller die; directly coupling each memory component to the controller die using signal lines associated with the plurality of TSVs; and encapsulating the controller die and the first semiconductor die with a molding compound. In an example, the first semiconductor die is coupled to the top surface of the controller die using a plurality of solder balls. In an example, the method also includes initiating a reflow process to melt the plurality of solder balls. In an example, the reflow process is initiated after the first semiconductor die is coupled to the top surface of the controller die. In an example, the reflow process is a mass reflow process that is initiated after a second semiconductor die is placed on a top surface of the first semiconductor die and after the first semiconductor die is placed on the controller die.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A semiconductor device, comprising:
a semiconductor die having a first non-volatile storage structure and a second non-volatile storage structure;
a first set of signal lines communicatively coupling the first non-volatile storage structure to a controller die of the semiconductor device, the first set of signal lines provided in a first set of through silicon vias (TSVs) and enabling a first set of data to be directly written to the first non-volatile storage structure; and
a second set of signal lines communicatively coupling the second non-volatile storage structure to the controller die of the semiconductor device, the second set of signal lines provided in a second set of TSVs and enabling a second set of data to be directly written to the second non-volatile storage structure independently from, and in parallel with, the first set of data.

2. The semiconductor device of claim 1, further comprising a TSV channel, the TSV channel including at least one of a first signal line from the first set of signal lines and a first signal line from the second set of signal lines.

3. The semiconductor device of claim 1, wherein the TSV channel is provided in a middle portion of the semiconductor die.

4. The semiconductor device of claim 1, wherein at least a portion of the first set of TSVs are positioned between the first non-volatile storage structure and the second non-volatile storage structure.

5. The semiconductor device of claim 1 wherein the semiconductor die is a first semiconductor die, the semiconductor device further comprising:
a second semiconductor die stacked on the first semiconductor die and having a third non-volatile storage structure and a fourth non-volatile storage structure;
a third set of signal lines communicatively coupling the third non-volatile storage structure to the controller die of the semiconductor device, the third set of signal lines provided in a third set of TSVs and enabling a third set of data to be directly written to the third non-volatile storage structure independently from, and in parallel with, the first set of data and the second set of data; and
a fourth set of signal lines communicatively coupling the fourth non-volatile storage structure to the controller die of the semiconductor device, the fourth set of signal lines provided in a fourth set of TSVs and enabling a fourth set of data to be directly written to the fourth non-volatile storage structure independently from and in parallel with, the first set of data, the second set of data and the third set of data.

6. The semiconductor device of claim 5, wherein at least one TSV in the first group of TSVs and at least one TSV is the third group of TSVs communicatively couple the first non-volatile storage structure and the third non-volatile storage structure.

7. The semiconductor device of claim 5, wherein at least one TSV from the third set of TSVs and at least one TSV from the fourth set of TSVs are positioned between the third non-volatile storage structure and the fourth non-volatile storage structure.

8. The semiconductor device of claim 1, wherein the first non-volatile storage structure and the second non-volatile storage structure are three dimensional (3D) NAND planes.

9. The semiconductor device of claim 1, further comprising a plurality of connection points provided on a bottom surface of the controller die, wherein each connection point of the plurality of connection points is associated with a TSV in the first group of TSVs and the second group of TSVs.

10. A non-volatile memory device, comprising:
a first semiconductor die having a first non-volatile storage means and a second non-volatile storage means, the first semiconductor die being stacked on a control means of the non-volatile memory device;
a first group of via means adjacent to the first non-volatile storage means and the second non-volatile storage means, the first group of via means being associated with signal means that directly couple the first non-volatile storage means to the control means of the non-volatile storage memory device and independently directly couple the second non-volatile storage means to the control means of the non-volatile memory device;
a second semiconductor die stacked on the first semiconductor die, the second semiconductor die having a third non-volatile storage means and a fourth non-volatile storage means; and
a second group of via means adjacent to the third non-volatile storage means and the fourth non-volatile storage means, the second group of via means being associated with signal means that directly couple the third non-volatile storage means to the control means of the non-volatile memory device and independently directly couple the fourth non-volatile storage means to the control means of the non-volatile memory device.

11. The non-volatile memory device of claim 10, further comprising a plurality of via means provided on the first semiconductor die, the first plurality of via means being associated with signal means that directly couple one or more of the first non-volatile storage means and the second non-volatile storage means to the control means of the non-volatile memory device.

12. The non-volatile memory device of claim 11, wherein the plurality of via means is provided in a middle portion of the first semiconductor die.

13. The non-volatile memory device of claim 10, wherein at least one via means in the first group of via means and at least one via means in the third group of via means communicatively couple the first non-volatile storage means and the third non-volatile storage means.

14. The non-volatile memory device of claim 10, wherein the first non-volatile storage means is a three-dimensional (3D) NAND plane.

15. The non-volatile memory device of claim 10, further comprising a plurality of connection means provided on a bottom surface of the control means, wherein each connection means of the plurality of connection means is associated with a TSV in the first group of via means and the second group of via means.

16. A method of fabricating a non-volatile memory device having a plurality of through silicon vias (TSVs) comprising:
fabricating a plurality of semiconductor dies, each semiconductor die of the plurality of semiconductor dies having a plurality of TSVs and a plurality of memory components;
placing a controller die on a substrate, the controller die including a plurality of TSVs;
coupling a first semiconductor die of the plurality of semiconductor dies to a top surface of the controller die such that the plurality of TSVs of the first semiconductor die are aligned with respective TSVs of the controller die;
directly coupling each memory component to the controller die using signal lines associated with the plurality of TSVs; and
encapsulating the controller die and the first semiconductor die with a molding compound.

17. The method of claim 16, wherein the first semiconductor die is coupled to the top surface of the controller die using a plurality of solder balls.

18. The method of claim 17, further comprising initiating a reflow process to melt the plurality of solder balls.

19. The method of claim 18, wherein the reflow process is initiated after the first semiconductor die is coupled to the top surface of the controller die.

20. The method of claim 18, wherein the reflow process is a mass reflow process that is initiated after a second semiconductor die is placed on a top surface of the first semiconductor die and after the first semiconductor die is placed on the controller die.
